(19) United States
(12) Patent Application Publication
(10) Pub. No.: US 2021/0408139 A1
(43) Pub. Date: Dec. 30, 2021

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yuanhang LI, Wuhan, Hubei (CN)

(21) Appl. No.: 16/645,504

(22) PCT Filed: Dec. 19, 2019
(86) PCT No.: PCT/CN2019/126661

§ 371 Date: Mar. 9, 2020

(30) Foreign Application Priority Data
Sep. 4, 2019 (CN) 201910832636.5

(51) Int. Cl. H01L 27/32; H01L 27/15; G06F 3/041

(52) U.S. Cl. CPC H01L 27/323; H01L 27/322; H01L 27/3272; G06F 2203/04107; G06F 3/0412; H01L 2227/323; G06F 2203/04103; H01L 27/156

(57) ABSTRACT

A display panel and a manufacturing method thereof, the display panel includes a light emitting layer and a touch layer located above the light emitting layer. The light emitting layer includes a plurality of light emitting units. The touch layer includes: a touch wiring layer and a filter structure. The filter structure includes a plurality of filters which are disposed in a plurality of gaps of the touch wiring layer respectively, the plurality of filters correspond to the plurality of light emitting units, and the projection of each of the filters on the light emitting layer covers the light emitting unit corresponding to the filter.

### TECHNICAL FIELD

The present application relates to a field of display technology, and more particularly, to a display panel and a manufacturing method thereof.

### BACKGROUND

In order to reduce the thickness of an electronic device with a touch function, in the prior art, a touch structure is usually integrated directly above a display panel by direct on touch (DOT) technology. Compared with an external touch structure, the DOT structure is thinner as well as lighter and has a higher light transmittance, it can be applied to flexible display panels.

### Technical Problem

In the prior art, a DOT structure is integrated above a polarizer layer of a display panel. The polarizer layer is composed of polarizers, which is used to reduce the reflectivity of the display panel under strong light. Generally, the thickness of the polarizers is about 100 micrometers, which is not conducive to reducing the thickness of the display panel. Moreover, the polarizers make the light output of the display panel seriously reduce, which affects display effects of the display panel and accelerates aging of the display panel.

### Technical Solution

The present application provides a display panel and a manufacturing method thereof to improve the light transmittance of the display panel and reduce the thickness of the display panel.

The present application provides a display panel, comprising a light emitting layer and a touch layer located above the light emitting layer,

wherein the light emitting layer comprises a plurality of light emitting units;

wherein the touch layer comprises:

a touch wiring layer comprising a plurality of gaps disposed corresponding to the plurality of light emitting units; and

a filter structure comprising a plurality of filters disposed in the plurality of gaps of the touch wiring layer respectively, the plurality of filters corresponding to the plurality of light emitting units, and a projection of each of the filters on the light emitting layer covering the light emitting unit corresponds to the filter,

wherein the touch wiring layer comprises a first metal layer, a shielding layer, and a second metal layer, the shielding layer covers the first metal layer, the second metal layer is located on the shielding layer and is electrically connected with the first metal layer by vias.

According to an aspect of the present application, the display panel further comprising an isolation layer located between the light emitting layer and the touch layer, and the first metal layer is disposed on the isolation layer.

According to an aspect of the present application, the plurality of filters correspond to the plurality of light emitting units, any one of the light colors retained by the filters is as same as the color of light emitted by the light emitting unit corresponding to the filter, an edge of any one of the filters covers an edge of the shielding layer adjacent to the filter.

According to an aspect of the present application, a sum of areas of the plurality of gaps is larger than a sum of areas of the plurality of light emitting units.

According to an aspect of the present application, the touch wiring layer further comprises a planarization layer covering the shielding layer and the filter structure, and the second metal layer is located on the planarization layer and is electrically connected with the first metal layer by vias.

Accordingly, the present application further light transmittance a method for manufacturing a display panel, comprising steps of:

forming a light emitting layer, the light emitting layer comprising a plurality of light emitting units;

forming a touch wiring layer above the light emitting layer, the touch wiring layer comprising a plurality of gaps, and the plurality of gaps disposed corresponding to the plurality of light emitting units; and

forming a filter structure, the filter structure comprising a plurality of filters, the plurality of filters disposed in the plurality of gaps of the touch wiring layer respectively, the plurality of filters corresponding to the plurality of filters, and a projection of each of the filters on the light emitting layer covering the light emitting unit corresponding to the filter,

wherein forming the touch wiring layer comprises the steps of:

forming a first metal layer;

forming a shielding layer, the shielding layer covering the first metal layer; and

forming a second metal layer, the second metal layer located on the shielding layer and electrically connected with the first metal layer by vias.

According to an aspect of the present application, after forming the light emitting layer, the method further comprises a step of:

forming an isolation layer, the isolation layer located on the light emitting layer.

According to an aspect of the present application, forming the first metal layer and the shielding layer comprises:

forming a metal thin film, the metal thin film covering the isolation layer;

forming a black photoresist, the black photoresist covering the metal thin film;

patterning the black photoresist to form the shielding layer; and

by taking the black photoresist as a mask, patterning the metal thin film to form the first metal layer.

According to an aspect of the present application, the plurality of filters correspond to the plurality of light emitting units, any one of the light colors retained by the filters is as the same as the color of light emitted by the light emitting unit corresponding to the filter, an edge of any one of the filters covers an edge of the shielding layer adjacent to the filter.

According to an aspect of the present application, after forming the shielding layer, the method further comprises a step of:

forming a planarization layer, the planarization layer covering the shielding layer and the filter structure.

### Beneficial Effect

Polarizers in the prior art are replaced by filters integrated in a touch structure according to the present application, it effectively reduces the thickness of the display panel. Moreover, since the light transmittance of the filters is much higher than that of the polarizers, the light transmittance of the display panel is effectively improved, and display effects as well as the life of the display panel are enhanced according to the present application. Moreover, metal layers in the touch structure are patterned by taking a light-shielding black matrix located between the filters as a mask, it reduces the number of masks used to pattern the metal layers, and the manufacturing processes is simplified as well as the manufacturing cost is saved.

### DESCRIPTION OF DRAWINGS

FIG. 1 is a schematic structural diagram showing a display panel according to a specific embodiment of the present application.

FIG. 2 is a top-view diagram of the display panel in FIG. 1.

FIG. 3 is a partial enlargement diagram of the display panel in FIG. 1.

### DETAILED DESCRIPTION OF PREFERRED EMBODIMENTS

The following descriptions for the respective embodiments are specific embodiments capable of being implemented for illustrating the present application with referring to the appending figures. In describing the present application, spatially relative terms such as “upper”, “lower”, “front”, “back”, “left”, “right”, “inner”, “outer”, “lateral”, and the like, may be used herein for ease of description as illustrated in the figures. Therefore, the spatially relative terms used herein are intended to illustrate the present application for ease of understanding, but are not intended to limit the present application. In the appending figures, units with similar structures are indicated by same reference numbers.

The present application provides a display panel and a manufacturing method thereof to improve the light transmittance of the display panel and reduce the thickness of the display panel.

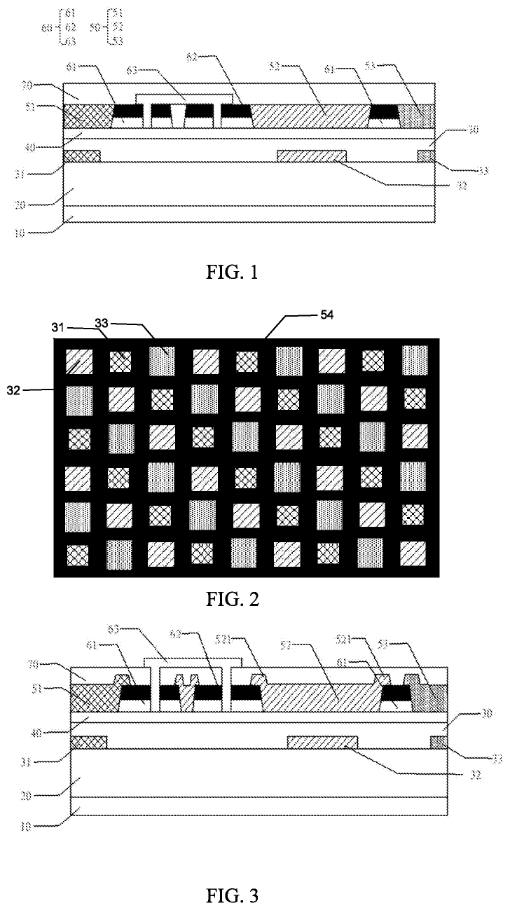

Referring to FIG. 1 to FIG. 3, FIG. 1 is a schematic structural diagram showing a display panel according to a specific embodiment of the present application, FIG. 2 is a top-view diagram of the display panel in FIG. 1, and FIG. 3 is a partial enlargement diagram of the display panel in FIG. 1. The display panel includes a substrate 10, a thin film transistor layer 20, a light emitting layer 30, and a touch layer located above the light emitting layer 30. In the present embodiment, the display panel further includes an isolation layer 40, which is located between the light emitting layer 30 and the touch layer.

The light emitting layer 30 includes a plurality of light emitting units. The plurality of light emitting units include red light emitting units 31, blue light emitting units 32, and green light emitting units 33. The plurality of light emitting units are isolated by a pixel definition layer.

In the present application, the touch layer includes a touch wiring layer 60 and a filter structure 50.

The touch wiring layer 60 includes a plurality of gaps, and the plurality of gaps are disposed corresponding to the plurality of light emitting units. The filter structure 50 includes a plurality of filters, and the plurality of filters are disposed in a plurality of gaps of the touch wiring layer 60 respectively. The touch wiring layer 60 includes a first metal layer 61, a shielding layer 62, and a second metal layer 63. The shielding layer 62 covers the first metal layer 61, and the second metal layer 63 is located on the shielding layer 62 and is electrically connected with the first metal layer 61 by vias. Wherein, a projection of the plurality of gaps on the light-emitting surface of the display panel do not overlap a projection of the first metal layer 61 and the second metal layer 63 on the light emitting layer 30.

The plurality of filters corresponds to the plurality of light emitting units, and any one of the light colors retained by the filters is as the same as the color of light emitted by the light emitting unit corresponding to the filter. For example, in the present embodiment, a filter disposed corresponding to the red light emitting unit 31 is a red filter 51, a filter disposed corresponding to the blue light emitting unit 32 is a blue filter 52, and a filter disposed corresponding to the green light emitting unit 33 is a green filter 53.

In the present application, the touch wiring layer 60 further includes a planarization layer 70. The planarization layer 70 covers the shielding layer 62 and the filter structure 50. The second metal layer 63 is located on the planarization layer 70 and is electrically connected with the first metal layer 61 by vias.

In the present application, the shielding layer 62 covers the first metal layer 61. The plurality of gaps are used to dispose a plurality of filters. In the present embodiment, a projection of each of the gaps on the light emitting layer covers the light emitting unit corresponding to the gap, and the area of each of the gaps is larger than the area of the light emitting unit corresponding to the gap. The light emitted by the light emitting unit can be ensured to completely enter the filters and avoid light loss according to this arrangement.

Referring to FIG. 3, according to a preferred embodiment of the present application, in order to ensure that the plurality of filters are located above the corresponding light emitting structure, an edge of any one of the filters covers an edge of the shielding layer 62 adjacent to the filter. “Horn-shaped” structures are formed to prevent light-leakage gaps from being produced between the filter and the shielding layer 62. In FIG. 3, the red filter 51 is taken as an example, an edge of the red filter 51 covers an edge of the shielding layer 62 adjacent to the red filter 51, so that the red filter 51 is in close contact with the light shielding layer 62 for eliminating light-leakage gaps produced possibly.

Referring to FIG. 2, which is the top-view diagram of the display panel in FIG. 1. In the present application, the shielding layer 62 serves as a black matrix and forms a filter structure with a plurality of filters, which can eliminate the light reflection of the display panel under strong light and replace the polarizers. Moreover, the filter structure is integrated in the touch layer 40, and the shielding layer 54 can be taken as a mask to pattern the touch wiring layer. According to an aspect of this design, it effectively reduces the thickness of the display panel, according to another aspect of this design, it reduces the number of masks used for patterning metal layers, the manufacturing processes is simplified as well as the manufacturing cost is saved.

Similarly, in order to ensure filtering effects of the filter structure, an edge of any one of the filters covers an edge of the shielding layer 54 adjacent to the filter, as shown in FIG. 1 and FIG. 3.

In the present embodiment, in order to eliminate the light reflection on lateral sides of the shielding layer 54, the area of the shielding layer 54 is larger than the area of the second metal layer 43, and a projection of the shielding layer 54 on the light emitting layer 30 covers a projection of the second metal layer 43 on the light emitting layer 30.

Accordingly, the present application also light transmittance a method for manufacturing a display panel, which includes the steps of.

First, an emitting layer 30 is formed. In the present embodiment, the emitting layer 30 includes a plurality of light emitting units. The plurality of light emitting units include red light emitting units 31, blue light emitting units 32, and green light emitting units 33. The plurality of light emitting units are isolated by a pixel definition layer.

Then, a wiring layer 60 and a filter structure 50 are formed above the light emitting layer 30. The touch wiring layer 60 includes a plurality of gaps, and the plurality of gaps are disposed corresponding to the plurality of light emitting units. The filter structure 50 includes a plurality of filters, and the plurality of filters are disposed in the plurality of gaps of the touch wiring layer 60 respectively. The plurality of filters correspond to the plurality of light emitting units, and any one of the light colors retained by the filters is as the same as the color of light emitted by the light emitting unit corresponding to the filter. For example, in the present embodiment, a filter disposed corresponding to the red light emitting unit 31 is a red filter 51, a filter disposed corresponding to the blue light emitting unit 32 is a blue filter 52, and a filter disposed corresponding to the green light emitting unit 33 is a green filter 53.

Finally, a planarization layer 70 is formed, and the planarization layer 70 covers the shielding layer 62 and the filter structure 50.

In the present application, after forming the light emitting layer 30, the method further includes a step of: forming an isolation layer 40, and the isolation layer 40 is located on the light emitting layer 30. The isolation layer 40 is used to protect an encapsulation structure on the surface of the light emitting layer 30 for preventing encapsulation thin films from being damaged by subsequent processes and the encapsulation structure of the light emitting layer 30 are broken.

In the present application, the method for forming the touch wiring layer 60 includes the steps of: forming a first metal layer 61; forming a shielding layer 62 which covers the first metal layer 61; and forming a second metal layer 63 which is located on the shielding layer 62 and is electrically connected with the first metal layer 61 by vias. A projection of the plurality of gaps on the light-emitting surface of the display panel do not overlap a projection of the first metal layer 61 and the second metal layer 63 on the light emitting layer 30.

In the present application, a method for forming the first metal layer 61 and the shielding layer 62 includes: forming a metal thin film which covers the isolation layer; forming a black photoresist which covers the metal thin film; patterning the black photoresist to form the shielding layer 62; and by taking the black photoresist as a mask, patterning the metal thin film to form the first metal layer 61.

In the present application, the shielding layer 62 serves as a black matrix and forms a filter structure with a plurality of filters, which can eliminate the light reflection of the display panel under strong light and replace the polarizers. Moreover, the filter structure is integrated in the touch layer, and the shielding layer 62 can be taken as a mask to pattern the touch wiring layer. According to an aspect of this design, it effectively reduces the thickness of the display panel, according to another aspect of this design, it reduces the number of masks used for patterning metal layers. The manufacturing processes is simplified as well as the manufacturing cost is saved

In the present application, the shielding layer 62 covers the first metal layer 61. The plurality of gaps are used to dispose a plurality of filters. Referring to FIG. 3, according to a preferred embodiment of the present application, in order to ensure that the plurality of filters are located above the corresponding light emitting structure, that is, an edge of any one of the filters covers an edge of the shielding layer 62 adjacent to the filter, and a sum of areas of the plurality of gaps is greater than a sum of areas of the plurality of light emitting units.

Polarizers in the prior art are replaced by filters integrated in a touch structure according to the present application, it effectively reduces the thickness of the display panel. Moreover, since the light transmittance of the filters is much higher than that of the polarizers, the light transmittance of the display panel is effectively improved, and display effects as well as the life of the display panel are enhanced according to the present application. Moreover, the metal layers in the touch structure are patterned by taking the light-shielding black matrix located between the filters as a mask, it reduces the number of masks used to pattern the metal layers, and the manufacturing processes is simplified as well as the manufacturing cost is saved.

Above all, although the present application has been disclosed above in the preferred embodiments, the above preferred embodiments are not intended to limit the present application. For persons skilled in this art, various modifications and alterations can be made without departing from the spirit and scope of the present application. The protective scope of the present application is subject to the scope as defined in the claims.

What is claimed is:

1. A display panel, comprising a light emitting layer and a touch layer located above the light emitting layer,
wherein the light emitting layer comprises a plurality of light emitting units;
wherein the touch layer comprises:
a touch wiring layer comprising a plurality of gaps disposed corresponding to the plurality of light emitting units; and
a filter structure comprising a plurality of filters disposed in the plurality of gaps of the touch wiring layer respectively, the plurality of filters corresponding to the plurality of light emitting units, and a projection of each of the filters on the light emitting layer covering the light emitting unit corresponds to the filter,
wherein the touch wiring layer comprises a first metal layer, a shielding layer, and a second metal layer, the shielding layer covers the first metal layer, the second metal layer is located on the shielding layer and is electrically connected with the first metal layer by vias.

2. The display panel as claimed in claim 1, further comprising an isolation layer located between the light emitting layer and the touch layer, and the first metal layer is disposed on the isolation layer.

3. The display panel as claimed in claim 1, wherein any one of the light colors retained by the filters is as same as the color of light emitted by the light emitting unit corresponding to the filter, an edge of any one of the filters covers an edge of the shielding layer adjacent to the filter.

4. The display panel as claimed in claim 3, wherein a sum of areas of the plurality of gaps is larger than a sum of areas of the plurality of light emitting units.

5. The display panel as claimed in claim 3, wherein the touch wiring layer further comprises a planarization layer covering the shielding layer and the filter structure, and the second metal layer is located on the planarization layer and is electrically connected with the first metal layer by vias.

6. A method for manufacturing a display panel, comprising steps of:
forming a light emitting layer, the light emitting layer comprising a plurality of light emitting units;
forming a touch wiring layer above the light emitting layer, the touch wiring layer comprising a plurality of gaps, and the plurality of gaps disposed corresponding to the plurality of light emitting units; and
forming a filter structure, the filter structure comprising a plurality of filters, the plurality of filters disposed in the plurality of gaps of the touch wiring layer respectively, the plurality of filters corresponding to the plurality of filters, and the projection of each of the filters on the light emitting layer covering the light emitting unit corresponding to the filter,
wherein forming the touch wiring layer comprises the steps of:
forming a first metal layer;
forming a shielding layer, the shielding layer covering the first metal layer; and
forming a second metal layer, the second metal layer located on the shielding layer and electrically connected with the first metal layer by vias.

7. The method as claimed in claim 6, wherein after forming the light emitting layer, the method further comprises a step of:
forming an isolation layer, the isolation layer located on the light emitting layer.

8. The method as claimed in claim 7, wherein forming the first metal layer and the shielding layer comprises:
forming a metal thin film, the metal thin film covering the isolation layer;
forming a black photoresist, the black photoresist covering the metal thin film;
patterning the black photoresist to form the shielding layer; and
by taking the black photoresist as a mask, patterning the metal thin film to form the first metal layer.

9. The method as claimed in claim 7, wherein the plurality of filters correspond to the plurality of light emitting units, any one of the light colors retained by the filters is as the same as the color of light emitted by the light emitting unit corresponding to the filter, the edge of any one of the filters covers the edge of the shielding layer adjacent to the filter.

10. The method as claimed in claim 7, wherein after forming the shielding layer, the method further comprises a step of:
forming a planarization layer, the planarization layer covering the shielding layer and the filter structure.
